(19) United States
(12) Patent Application Publication
(10) Pub. No.: US 2025/0096524 A1
(43) Pub. Date: Mar. 20, 2025

(54) SEMICONDUCTOR LASER LIGHT SOURCE DEVICE

(71) Applicant: Mitsubishi Electric Corporation, Tokyo (JP)

(72) Inventors: Hayata FUKUSHIMA, Tokyo (JP); Seiji NAKANO, Tokyo (JP)

(73) Assignee: Mitsubishi Electric Corporation, Tokyo (JP)

(21) Appl. No.: 18/727,643

(22) PCT Filed: Jun. 1, 2022
(86) PCT No.: PCT/JP2022/022332

§ 371 Date: Jul. 9, 2024

(51) Int. Cl. H01S 5/024; H01S 5/0231; H01S 5/02345; H01S 5/026

(52) U.S. Cl. CPC H01S 5/02407; H01S 5/0231; H01S 5/02345; H01S 5/0265

(57) ABSTRACT

A temperature control module (4) is mounted on the metal stem (1). A support block (5) is provided on the temperature control module. A back surface of a dielectric substrate (6) is joined to a side surface of the support block. A differential driving signal line (7a,7b) is provided and a semiconductor light modulation device (10) is mounted on a principal surface of the dielectric substrate. A first lead pin (2b,2c) is connected to one end of the differential driving signal line. The other end of the differential driving signal line is wire-connected to the semiconductor light modulation device. The temperature control module is wire-connected to the second lead pin (2e,2f). The dielectric substrate has a cutout (6a) on a side of the metal stem. Parts of the temperature control module and the support block are positioned in an internal space of the cutout.

### FIELD

The present disclosure relates to a semiconductor laser light source device that controls a temperature of a semiconductor light modulation device with a temperature control module.

### BACKGROUND ART

SNS, video-sharing services, and the like have spread on a worldwide scale, accelerating increase in capacity of data transmission. To support signal transmission at higher speed and with larger capacity in a limited mounting space, increase in speed and reduction in size of an optical transceiver have been promoted. In addition to higher speed and lower cost, an optical device is required to achieve lower power consumption to reduce running cost.

As a structure of a laser light source device equipped with a semiconductor light modulation device, a transistor-outlined CAN (TO-CAN) type that can be brought to production at low cost is typically adopted. In a structure of the TO-CAN, typically, lead pins are sealed and fixed to a metal stem using glass. A pressure by a difference in thermal expansion coefficients is utilized, and thus, arrangement of the lead pins and an interval between the lead pins are important to secure high airtightness.

An oscillation wavelength or light output of the semiconductor light modulation device changes by a temperature change by heat generation. Thus, a temperature control module is used in the laser light source device equipped with the semiconductor light modulation device to keep a temperature of the semiconductor light modulation device constant (see, for example, PTL 1).

### CITATION LIST

### Patent Literature

[PTL 1] JP 5188625 B

### SUMMARY

### Technical Problem

In a structure in related art, a semiconductor modulation element is mounted on a first dielectric substrate, a second dielectric substrate is mounted on a support block on a metal stem, a high-frequency line of the second dielectric substrate is joined to lead pins, and a high-frequency line of the first dielectric substrate is connected to the high-frequency line of the second dielectric substrate with a conductive wire. Thus, high-frequency characteristics deteriorate due to impedance mismatch between the lead pins and the semiconductor modulation element or increase in inductance components. Further, existence of the second dielectric substrate and the support block on which the second dielectric substrate is mounted increases cost. Still further, an electrical signal is input to the semiconductor light modulation device using a single-phase drive scheme, which increases power consumption.

The present disclosure has been made to solve the problems as described above, and an object of the present disclosure is to provide a semiconductor laser light source device capable of improving high-frequency characteristics and reducing cost and power consumption.

### Solution to Problem

A semiconductor laser light source device according to the present disclosure includes: a metal stem; first and second lead pins penetrating through the metal stem; a temperature control module mounted on the metal stem; a support block provided on the temperature control module; a dielectric substrate having a principal surface and a back surface opposite to each other, the back surface joined to a side surface of the support block; a differential driving signal line provided on the principal surface of the dielectric substrate; a semiconductor light modulation device mounted on on the principal surface of the dielectric substrate; a conductive joining material connecting the first lead pin and one end of the differential driving signal line; a first conductive wire connecting the other end of the differential driving signal line and the semiconductor light modulation device; and a second conductive wire connecting the temperature control module and the second lead pin, wherein the dielectric substrate has a cutout on a side of the metal stem, and parts of the temperature control module and the support block are positioned in an internal space of the cutout.

Advantageous Effects of Invention

In the present disclosure, the dielectric substrate has the cutout on a side of the metal stem, and parts of the temperature control module and the support block are positioned in an internal space of the cutout. By this means, the dielectric substrate on which the semiconductor light modulation device is mounted can extend close to the metal stem, so that the differential driving signal lines of the dielectric substrate can be connected to the lead pins without intervention of the other dielectric substrates. This leads to improvement in high-frequency characteristic and it is possible to reduce cost. Further, an electrical signal is input to the semiconductor light modulation device using a differential drive scheme, which can reduce a voltage amplitude of the signal generator compared to a single-phase drive scheme in related art, so that it is possible to reduce power consumption of the signal generator.

### BRIEF DESCRIPTION OF THE DRAWINGS

FIG. 1 is a front perspective view illustrating a semiconductor device according to a first embodiment.

FIG. 2 is a top view illustrating a semiconductor laser light source device according to the first embodiment.

FIG. 3 is a side view illustrating the semiconductor laser light source device according to the first embodiment.

FIG. 4 is a rear perspective view illustrating the semiconductor laser light source device according to the first embodiment.

FIG. 5 is a rear perspective view illustrating a semiconductor laser light source device according to a second embodiment.

FIG. 6 is a top view illustrating a semiconductor laser light source device according to a third embodiment.

FIG. 7 is a rear perspective view illustrating the semiconductor laser light source device according to the third embodiment.

FIG. 8 is a side view illustrating a semiconductor laser light source device according to a fourth embodiment.

FIG. 9 is an enlarged view of a portion enclosed with a dashed line in FIG. 8.

FIG. 10 is a side perspective view illustrating the semiconductor laser light source device according to the fourth embodiment.

FIG. 11 is an enlarged view of a portion enclosed with a dashed line in FIG. 10.

FIG. 12 is a schematic view illustrating a semiconductor laser light source device according to a fifth embodiment.

### DESCRIPTION OF EMBODIMENTS

A semiconductor laser light source device according to the embodiments of the present disclosure will be described with reference to the drawings. The same components will be denoted by the same symbols, and the repeated description thereof may be omitted.

### First Embodiment

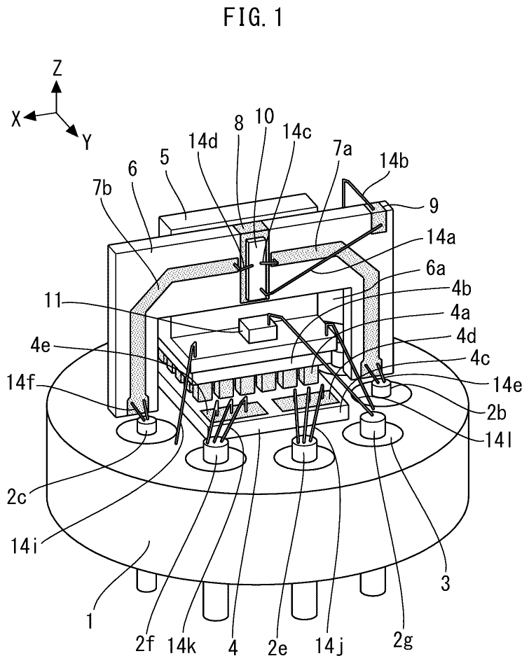

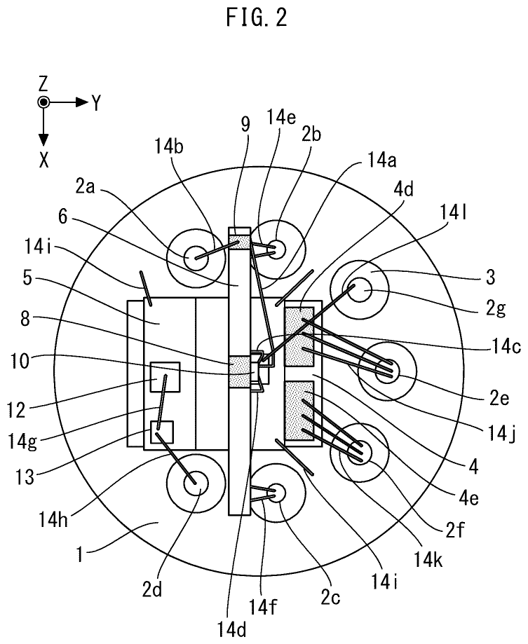

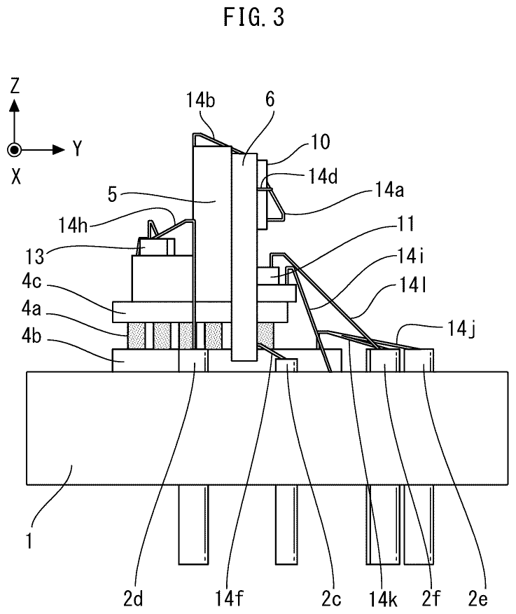

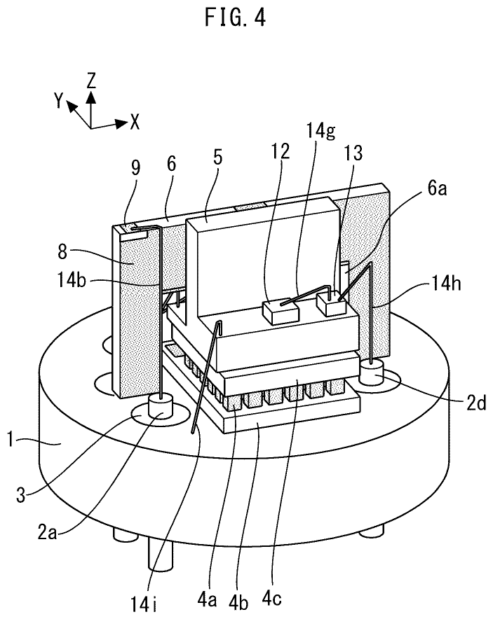

FIG. 1 is a front perspective view illustrating a semiconductor device according to a first embodiment. FIG. 2 is a top view illustrating a semiconductor laser light source device according to the first embodiment. FIG. 3 is a side view illustrating the semiconductor laser light source device according to the first embodiment. FIG. 4 is a rear perspective view illustrating the semiconductor laser light source device according to the first embodiment.

A metal stem 1 is a metal plate having a substantially circular shape. A plurality of lead pins 2a to 2g penetrate through the metal stem 1. Glass 3 is typically used to fix the lead pins 2a to 2g to the metal stem 1. Materials of the metal stem 1 and the lead pins 2a to 2g are, for example, metals such as copper, iron or stainless. Au plating, nickel plating, or the like, may be applied to surfaces of the metal stem 1 and the lead pins 2a to 2g. If impedance mismatch occurs, frequency response characteristics deteriorate due to signal multiple reflection, and it is difficult to perform high-speed modulation. Thus, the glass 3 is formed with a material with low permittivity so as to achieve the same impedance as impedance of a signal generator.

A temperature control module 4 is mounted on the metal stem 1. The temperature control module 4 is such that a plurality of thermoelectric elements 4a formed with a material such as, for example, BiTe are put between a lower substrate 4b and an upper substrate 4c formed with a material such as AlN. An upper surface of the metal stem 1 is jointed to the lower substrate 4b of the temperature control module 4 with a joining material such as, for example, SnAgCu solder or AuSn solder. The lower substrate 4b has a protruding portion protruding forward more than the upper substrate 4c, and metalized portions 4d and 4e for supplying power to the thermoelectric elements 4a are provided on the protruding portion.

A support block 5 is provided on the temperature control module 4. The support block 5 is a block formed with a metal material in which Au plating or the like is applied to a surface of a metal such as, for example, copper, iron or stainless. Note that the support block 5 may have a structure in which a metal is coated on an insulator such as a ceramic or a resin.

A dielectric substrate 6 has a principal surface and a back surface opposite to each other. The back surface of the dielectric substrate 6 is joined to a side surface of the support block 5. The dielectric substrate 6 is a U-shaped plate having a cutout 6a that is open toward the metal stem 1. The temperature control module 4 is positioned at the cutout 6a of the dielectric substrate 6. The dielectric substrate 6 is formed with a ceramic material such as, for example, aluminum nitride (AlN), and has an electrical insulating function and a heat transfer function. The dielectric substrate 6 may be integrally formed or may be formed by combining rectangular substrates.

Two differential driving signal lines 7a and 7b and a ground conductor 8 are provided on the principal surface of the dielectric substrate 6 through Au plating and metalization. The differential driving signal lines 7a and 7b are a microstrip line or a coplanar line and have impedance equivalent to output impedance of the signal generator. The ground conductor 8 is provided from the principal surface to the back surface of the dielectric substrate 6, and the ground conductor 8 on the back surface side is joined to the support block 5. Further, a signal conductor 9 is provided from the principal surface to an upper surface of the dielectric substrate 6.

A semiconductor light modulation device 10 is mounted on the dielectric substrate 6. A modulator portion of the semiconductor light modulation device 10 includes a plurality of electro-absorption optical modulators. The semiconductor light modulation device 10 is, for example, a modulator integrated-type laser diode (EAM-LD) obtained by monolithically integrating an electro-absorption optical modulator using an InGaAsP quantum-well absorption layer and a distributed-feedback laser diode. Laser light is emitted from a light emission point of the semiconductor light modulation device 10 along an optical axis perpendicular to a chip end surface and parallel to a chip principal surface.

A light receiving device 11, a temperature sensor 12 and a ceramic block 13 are mounted on the support block 5. As a joining material for joining the temperature sensor 12 and the ceramic block 13 to the support block 5, for example, SnAgCu solder, AuSn solder, or the like is used. The temperature sensor 12 is, for example, a thermistor. The ceramic block 13 is, for example, an AlN substrate. A conductive film is provided on an upper surface of the ceramic block 13. Here, the light receiving device 11 is positioned on a negative direction side on a Z axis of the semiconductor light modulation device 10.

A conductive wire 14a connects a distributed-feedback laser diode of the semiconductor light modulation device 10 and the signal conductor 9 on the principal surface of the dielectric substrate 6. Note that the distributed-feedback laser diode may be connected to the signal conductor 9 by way of a conductor provided on the principal surface of the dielectric substrate 6. A conductive wire 14b connects the signal conductor 9 on the upper surface of the dielectric substrate 6 and the lead pin 2a. Conductive wires 14c and 14d respectively connect one ends of the two differential driving signal lines 7a and 7b and an electro-absorption modulator

(EAM) electrode of the semiconductor light modulation device 10. Conductive wires 14e and 14f respectively connect the other ends of the two differential driving signal lines 7a and 7b and the lead pins 2b and 2c. Note that the other ends of the two differential driving signal lines 7a and 7b may be connected to the lead pins 2b and 2c using a conductive joining material such as, for example, SnAgCu solder or AuSn solder.

A conductive wire 14g connects the temperature sensor 12 and the conductive film of the ceramic block 13. A conductive wire 14h connects the conductive film of the ceramic block 13 and the lead pin 2d. A conductive wire 14i connects the support block 5 and the metal stem 1. A plurality of the conductive wires 14i may be connected to improve high-frequency characteristics by strengthening GND. Conductive wires 14j and 14k respectively connect the metalized portions 4d and 4e of the temperature control module 4 and the lead pins 2e and 2f. A conductive wire 14l connects the light receiving device 11 and the lead pin 2g.

Differential electrical signals input to the lead pins 2b and 2c are respectively transmitted to the differential driving signal lines 7a and 7b via the conductive wires 14e and 14fand applied to a modulator of the semiconductor light modulation device 10 via the conductive wires 14c and 14d. Here, the electrical signals input to the lead pins 2b and 2c are electromagnetically coupled to the metal stem 1. The metal stem 1 is connected to the support block 5 via the conductive wire 14i, and the support block 5 is connected to the ground conductor 8 of the dielectric substrate 6. Thus, the metal stem 1, the support block 5 and the ground conductor 8 act as an AC ground.

If a temperature of the semiconductor light modulation device 10 changes, an oscillation wavelength changes, and thus, it is necessary to keep the temperature constant. Thus, in a case where the temperature of the semiconductor light modulation device 10 rises, the temperature control module 4 performs cooling, and, inversely, in a case where the temperature decreases, the temperature control module 4 generates heat to keep the temperature of the semiconductor light modulation device 10 constant. The heat generated at the semiconductor light modulation device 10 is transferred to the upper substrate 4c of the temperature control module 4 via the dielectric substrate 6 and the support block 5. The temperature control module 4 absorbs the heat received from the semiconductor light modulation device 10. The heat absorbed by the temperature control module 4 is propagated in a negative direction on the Z axis from the lower substrate 4b of the temperature control module 4 via the metal stem 1 and dissipated on a lower surface side of the metal stem 1.

The temperature sensor 12 indirectly measures the temperature of the semiconductor light modulation device 10 via the dielectric substrate 6 and the support block 5. The measured temperature is fed back to the temperature control module 4, and the temperature control module 4 performs cooling in a case where the temperature of the semiconductor light modulation device 10 is high with respect to a target value, and generates heat in a case where the temperature is low. As a result, the temperature of the semiconductor light modulation device 10 can be stabilized.

If the temperature sensor 12 is directly wire-connected to the lead pin 2d, ambient temperature transferred from outside to the metal stem 1 flows into the temperature sensor 12 via the wire, and an accurate temperature cannot be measured. Thus, the ceramic block 13 is positioned between the temperature sensor 12 and the lead pin 2d to perform relay. This can reduce an amount of heat flowing into the temperature sensor 12, so that the temperature sensor 12 can measure an accurate temperature.

The light receiving device 11 converts (performs O/E conversion) an optical signal into an electrical signal. The electrical signal is transmitted to the lead pin 2g via the connected conductive wire 141. While the number of lead pins that penetrate through the metal stem 1 increases by one as a result of the light receiving device 11 being provided, intensity of backlight of the semiconductor light modulation device 10 can be monitored. By feeding back the monitoring result, it is possible to control a drive current of the semiconductor light modulation device 10 so as to make light output constant.

As described above, in the present embodiment, the dielectric substrate 6 has the cutout 6a on a side of the metal stem 1, and parts of the temperature control module 4 and the support block 5 are positioned in an internal space of the cutout 6a. By this means, the dielectric substrate 6 on which the semiconductor light modulation device 10 is mounted can extend close to the metal stem 1, so that the differential driving signal lines 7a and 7b of the dielectric substrate 6 can be connected to the lead pins 2b and 2c without intervention of the other dielectric substrates. This reduces signal reflection points, which leads to improvement in high-frequency characteristics.

Further, the second dielectric substrate in related art, the support block on which the second dielectric substrate is mounted, and a conductive wire that connects a signal line of the first dielectric substrate and a signal line of the second dielectric substrate are not required, so that it is possible to reduce cost.

Further, an electrical signal is input to the semiconductor light modulation device using a differential drive scheme, which can reduce a voltage amplitude of the signal generator compared to a single-phase drive scheme in related art, so that it is possible to reduce power consumption of the signal generator.

In a structure in related art, the second dielectric substrate exists between the semiconductor modulation element and the lead pin. Thus, a signal is reflected due to impedance mismatch at a connection point, which decreases a gain of a band. On the other hand, in the present embodiment, the second dielectric substrate is not required, and thus, a signal reflection point does not exist, so that it is possible to achieve a wider bandwidth than in the structure in related art.

In the structure in related art, heat flows into the first dielectric substrate on which the semiconductor light modulation device is mounted from the support block joined to the metal stem via the second dielectric substrate and the conductive wire, and thus, an amount of heat to be absorbed by the temperature control module increases, which leads to increase in power consumption. On the other hand, in the present embodiment, a support block joined to the metal stem is not provided, so that it is possible to reduce power consumption compared to the structure in related art.

To seal and fix the lead pins 2a to 2g to the metal stem 1 with the glass 3, typically, a compression scheme or a matching scheme is applied. It is important that each of the lead pins 2a to 2g has an equal pressure upon sealing to keep airtightness. It is therefore desirable that the lead pins 2a to 2g are arranged in a circular shape with respect to the metal stem 1. Further, if an interval between adjacent lead pins 2a to 2g is too close, sealing properties deteriorate, and thus, a certain degree of distance is required.

In the structure in related art, it is necessary to secure a space for providing the support block on which the second dielectric substrate is to be mounted, on the metal stem, and thus, the lead pins cannot be equally arranged, and airtightness cannot be achieved. On the other hand, in the present embodiment, the support block is not provided on the metal stem 1, so that the lead pins 2a to 2g can be equally arranged, thereby airtightness is improved.

Further, the lead pins 2b, 2c and 2e to 2g are arranged on the principal surface side of the dielectric substrate 6. On the other hand, the lead pin 2a for feeding power to the distributed-feedback laser diode of the semiconductor light modulation device 10, and the lead pin 2d for feeding power to the temperature sensor 12 are arranged on the back surface side of the dielectric substrate 6. This enables the lead pins 2a to 2g to be equally arranged in a circular shape with respect to the metal stem 1, so that airtightness is improved.

Further, the conductive wire 14a connects the distributed-feedback laser diode of the semiconductor light modulation device 10 and the signal conductor 9 of the dielectric substrate 6, and the conductive wire 14b connects the signal conductor 9 and the lead pin 2a. This makes it possible to supply electricity to the distributed-feedback laser diode of the semiconductor light modulation device 10 on the principal surface side of the dielectric substrate 6 from the lead pin 2a on the back surface side of the dielectric substrate 6 without using a complicated mechanism of a wire bonding device.

Further, if the dielectric substrate 6 is in contact with the metal stem 1, heat transferred from outside to the metal stem 1 flows into the semiconductor light modulation device 10 and the temperature sensor 12 via the dielectric substrate 6. This makes it difficult for the temperature control module 4 to perform temperature control. It is therefore desirable to prevent the dielectric substrate 6 and the metal stem 1 from coming into contact with each other.

Further, the lead pins 2b and 2c connected to the differential driving signal lines 7a and 7b have an inner lead portion protruding from an upper surface of the metal stem 1. As a length of the inner lead portion is made shorter, inductance components are reduced, a loss due to reflection of a signal at the inner lead portion can be reduced, and a passband is improved. Further, to obtain a maximum voltage amplitude from the signal generator, a matching resistor may be provided on the principal surface of the dielectric substrate 6 to be connected in parallel to the semiconductor light modulation device 10.

### Second Embodiment

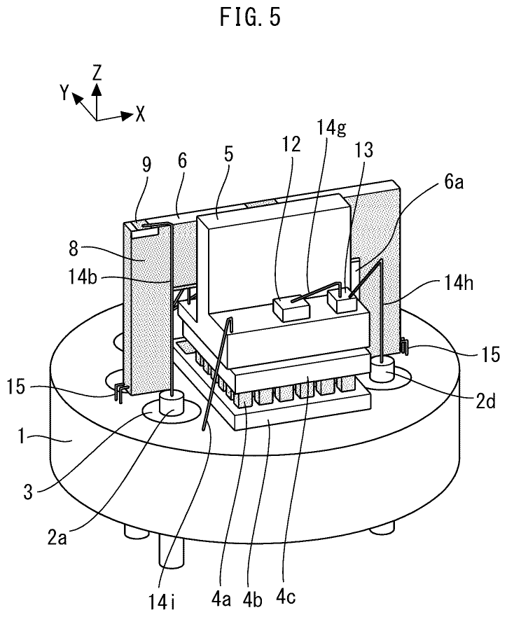

FIG. 5 is a rear perspective view illustrating a semiconductor laser light source device according to a second embodiment. The ground conductor 8 is provided also on the side surface of the dielectric substrate 6, which is orthogonal to the upper surface of the metal stem 1, in addition to the back surface of the dielectric substrate 6. Further, a conductive wire 15 connects the ground conductor 8 provided on the side surface of the dielectric substrate 6 and the metal stem 1. The conductive wire 15 is preferably connected on both sides of the lead pin 2b side and the lead pin 2c side, and a plurality of the conductive wires 15 may be connected on each of both sides.

In the first embodiment, a ground of the semiconductor modulation element passes from the ground conductor 8 of the dielectric substrate 6 to the support block 5 and is connected to the metal stem 1 via the conductive wire 14i. Thus, a distance to the ground is long, which may weaken the ground and may lead to deterioration of high-frequency characteristics. On the other hand, in the present embodiment, the ground of the semiconductor modulation element is connected to the metal stem 1 from the ground conductor 8 of the dielectric substrate 6 via the conductive wire 15, which makes a distance to the ground shorter and improves high-frequency characteristics. Further, as a result of the ground being connected by the conductive wire 15, it is possible to strengthen the ground more, while preventing heat from flowing into the dielectric substrate 6 from the metal stem 1, than a case where the ground is directly joined. Still further, by the ground conductor 8 being provided on the side surface of the dielectric substrate 6, the conductive wire 15 can be connected without changing the arrangement of the lead pins.

### Third Embodiment

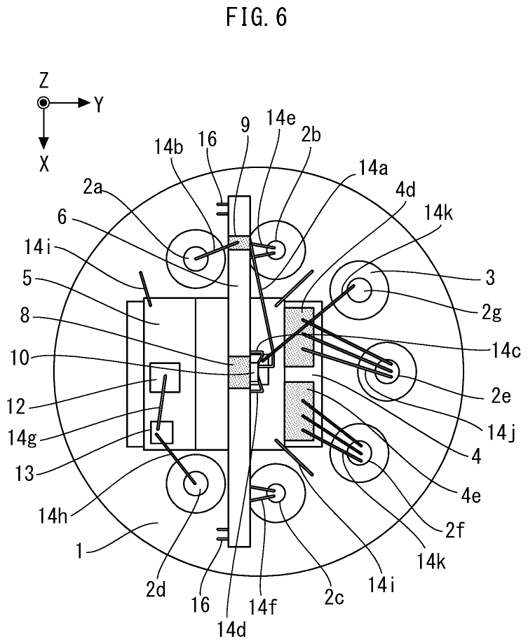

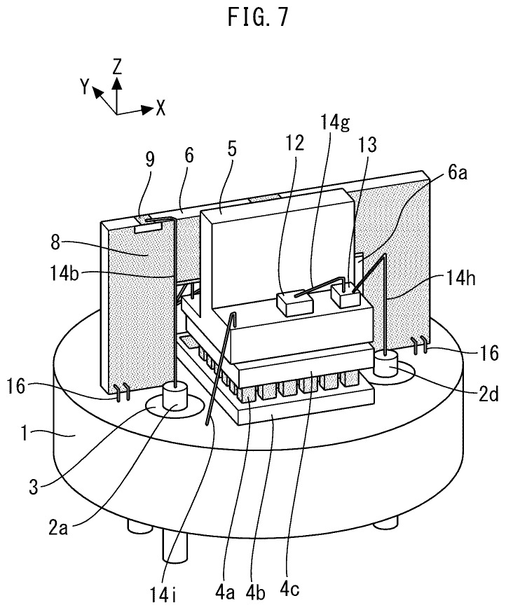

FIG. 6 is a top view illustrating a semiconductor laser light source device according to a third embodiment. FIG. 7 is a rear perspective view illustrating the semiconductor laser light source device according to the third embodiment.

The dielectric substrate 6 is expanded in both positive and negative directions on the X axis compared to that in the first embodiment and extends outward from the lead pins 2b and 2c in plan view. A conductive wire 16 connects the ground conductor 8 provided on the back surface of the dielectric substrate 6 and the metal stem 1. In a similar manner to the second embodiment, the conductive wire 16 is preferably connected on both sides of the lead pin 2b side and the lead pin 2c side, and a plurality of the conductive wires 16 may be connected on each of both sides.

According to the present embodiment, in a similar manner to the second embodiment, it is possible to strengthen the ground while preventing heat from flowing into the dielectric substrate 6 from the metal stem 1. Further, by the dielectric substrate 6 being expanded, the conductive wire 16 can be connected from the back surface of the dielectric substrate 6 without changing the arrangement of the lead pins.

### Fourth Embodiment

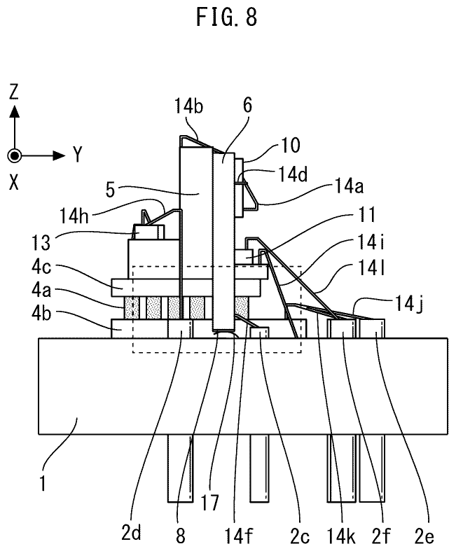

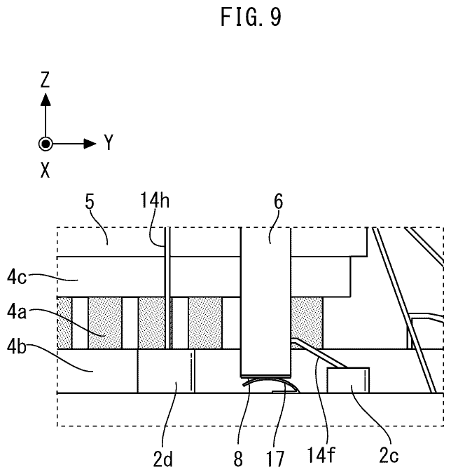

FIG. 8 is a side view illustrating a semiconductor laser light source device according to a fourth embodiment. FIG. 9 is an enlarged view of a portion enclosed with a dashed line in FIG.

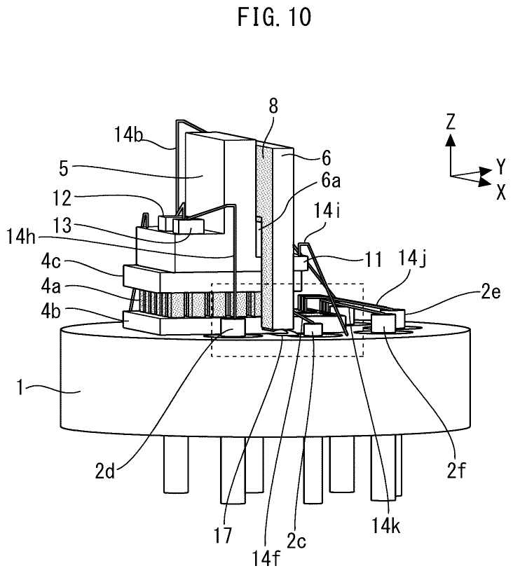

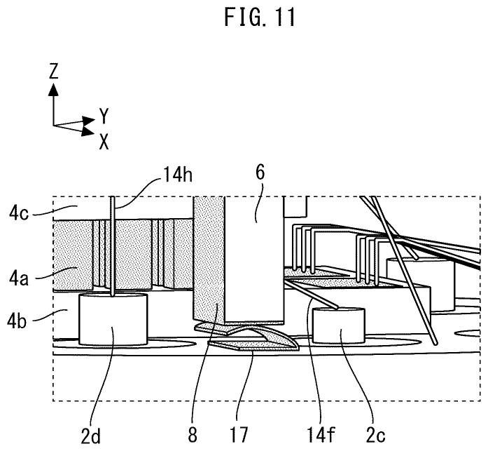

8. FIG. 10 is a side perspective view illustrating the semiconductor laser light source device according to the fourth embodiment. FIG. 11 is an enlarged view of a portion enclosed with a dashed line in FIG. 10.

The ground conductor 8 is provided also on the lower surface of the dielectric substrate 6, which faces the upper surface of the metal stem 1, in addition to the back surface of the dielectric substrate 6 at the right and left projecting portions of the dielectric substrate 6 to be connected to the lead pins 2b and 2c. Further, the ground conductor 8 provided on the lower surface of the dielectric substrate 6 is connected to the metal stem 1 by a conductive spring 17. One end of the conductive spring 17 is joined to the ground conductor 8 provided on the lower surface of the dielectric substrate 6 or the upper surface of the metal stem 1 using a joining material such as SnAgCu solder or AuSn solder. The conductive spring 17 is mounted so as to be pressed against the upper surface of the metal stem 1 by the dielectric substrate 6. The conductive spring 17 may be obtained by, for example, processing a metal material such as copper, iron or stainless in a shape of a leaf spring or a coil spring or may be a rubber material having conductivity.

In the present embodiment, by using the conductive spring 17, it is possible to reduce an area where the dielectric substrate 6 is in contact with the metal stem 1. It is therefore possible to strengthen the ground while preventing heat from flowing into the dielectric substrate 6 from the metal stem 1 in a similar manner to the second embodiment. Further, by providing the conductive spring 17 in a space between the dielectric substrate 6 and the metal stem 1, it is possible to strengthen the ground without changing the arrangement of the lead pins.

### Fifth Embodiment

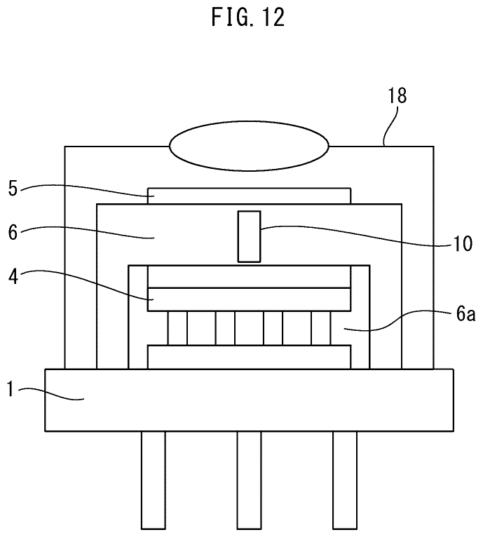

FIG. 12 is a schematic view illustrating a semiconductor laser light source device according to a fifth embodiment. A cap 18 with a lens is joined to the metal stem 1 of the semiconductor laser light source device according to any one of the first to the fourth embodiments. The cap 18 with a lens is a cap for hermetic seal that airtightly seals the temperature control module 4, the support block 5, the dielectric substrate 6, the semiconductor light modulation device 10, the temperature sensor 12, and the like, mounted on the metal stem 1. With the cap 18 with a lens, it is possible to improve moisture resistance and disturbance tolerance. The lens of the cap 18 with a lens is formed with glass made of, for example, SiO₂, and collects laser light emitted from the semiconductor light modulation device 10 and makes the laser light incident on a fiber.

### REFERENCE SIGNS LIST

1 metal stem; 2a-2g lead pin; 4 temperature control module; 5 support block; 6 dielectric substrate; 6a cutout; 7a,7b differential driving signal line; 8 ground conductor; 10 semiconductor light modulation device; 11 light receiving device; 12 temperature sensor; 13 ceramic block; 14a-14l,15,16 conductive wire; 17 conductive spring; 18 cap with a lens

1. A semiconductor laser light source device comprising:
a metal stem;
first and second lead pins penetrating through the metal stem;
a temperature control module mounted on the metal stem;
a support block provided on the temperature control module;
a dielectric substrate having a principal surface and a back surface opposite to each other, the back surface joined to a side surface of the support block;
a differential driving signal line provided on the principal surface of the dielectric substrate;
a semiconductor light modulation device mounted on on the principal surface of the dielectric substrate;
a conductive joining material connecting the first lead pin and one end of the differential driving signal line;
a first conductive wire connecting the other end of the differential driving signal line and the semiconductor light modulation device; and
a second conductive wire connecting the temperature control module and the second lead pin,
wherein the dielectric substrate has a cutout on a side of the metal stem, and
parts of the temperature control module and the support block are positioned in an internal space of the cutout.

2. The semiconductor laser light source device according to claim 1, further comprising a ground conductor provided on the back surface of the dielectric substrate and joined to the support block, and a third conductive wire connecting the support block and the metal stem.

3. The semiconductor laser light source device according to claim 1, further comprising a ground conductor provided on the back surface and a side surface of the dielectric substrate, and a third conductive wire connecting the ground conductor provided on the side surface of the dielectric substrate and the metal stem.

4. The semiconductor laser light source device according to claim 1, further comprising a ground conductor provided on the back surface of the dielectric substrate extending outward from the first lead pin, and a third conductive wire connecting the ground conductor and the metal stem.

5. The semiconductor laser light source device according to claim 1, further comprising a ground conductor provided on the back surface and a lower surface of the dielectric substrate, and a conductive spring connecting the ground conductor provided on the lower surface of the dielectric substrate and the metal stem.

6. The semiconductor laser light source device according to claim 1, further comprising a cap with a lens that is jointed to the metal stem and airtightly seals the temperature control module, the support block, the dielectric substrate, and the semiconductor light modulation device.

7. The semiconductor laser light source device according to 1, wherein the dielectric substrate does not come into contact with the metal stem.

8. The semiconductor laser light source device according to claim 1, wherein the conductive joining material is a conductive wire.

9. The semiconductor laser light source device according to claim 1, wherein the conductive joining material is solder.

10. The semiconductor laser light source device according to claim 1, further comprising a third lead pin penetrating through the metal stem, a temperature sensor mounted on the support block, and a fourth conductive wire connecting the temperature sensor and the third lead pin.

11. The semiconductor laser light source device according to claim 10, further comprising a ceramic block mounted on the support block, and a conductive film provided on the ceramic block, to anywherein the fourth conductive wire includes a conductive wire connecting the temperature sensor and the conductive film, and a conductive wire connecting the conductive film and the third lead pin.

12. The semiconductor laser light source device according to claim 1, wherein a modulator portion of the semiconductor light modulation device includes a plurality of electro-absorption optical modulators.

13. The semiconductor laser light source device according to claim 1, further comprising a light receiving device monitoring intensity of backlight of the semiconductor light modulation device.
